(19) United States
(12) Patent Application Publication
(10) Pub. No.: US 2008/0006851 A1
(43) Pub. Date: Jan. 10, 2008

(54) Non-volatile phase-change memory and manufacturing method thereof

(75) Inventors: Hiroshi Moriya, Ushiku (JP); Tomio Iwasaki, Tsukuba (JP)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Renesas Technology Corp., Tokyo (JP)

(21) Appl. No.: 11/825,401

(22) Filed: Jul. 6, 2007

(30) Foreign Application Priority Data
Jul. 10, 2006 (JP) 2006-189455

(51) Int. Cl. G11C 11/00

(52) U.S. Cl. 257/246; 365/163

(57) ABSTRACT

In a non-volatile phase-change memory comprising: an interlayer dielectric film and a plug formed on one main surface side of a silicon substrate; a phase-change film which can take a different electric resistivity depending on a phase change and is provided on surfaces of the interlayer dielectric film and the plug; and an upper electrode film formed on an upper surface of the phase-change film, a relation between a film thickness of the phase-change film and an amount of protrusion of the upper electrode film from the plug is set to 0.3≦L/T≦1. Thus, a density of current flowing through the phase-change film near the outer periphery of the plug is reduced, thereby suppressing migration and enabling rewriting with low energy. Accordingly, a reliable non-volatile phase-change memory can be achieved.

### CROSS-REFERENCE TO RELATED APPLICATION

The present application claims priority from Japanese Patent Application No. JP 2006-189455 filed on Jul. 10, 2006, the content of which is hereby incorporated by reference into this application.

### TECHNICAL FIELD OF THE INVENTION

The present invention relates to a technology for a non-volatile phase-change memory (PCM). More particularly, it relates to a technology effectively applied to a structure of a non-volatile phase-change memory and a manufacturing method thereof.

### BACKGROUND OF THE INVENTION

In recent years, a non-volatile phase-change memory (PCM) using a phase-change chalcogenide material has been suggested as a next-generation non-volatile semiconductor memory. Although being non-volatile, PCM is expected to be capable of high-speed memory write/read operations equivalent to those of a dynamic random access memory (DRAM). Also, since PCM can be integrated in a cell area equivalent to a FLASH memory, PCM is considered to be a most promising candidate as a next-generation non-volatile memory.

The chalcogenide material for use in PCM has already been used in a digital versatile disc (DVD). DVD utilizes the characteristic of the chalcogenide material that its optical reflectivity varies between an amorphous state and a crystalline state. On the other hand, PCM is a device operated as a memory by utilizing a characteristic of the phase-change material that its electric resistivity varies by several orders of magnitude between an amorphous state and a crystalline state.

In the switching of the non-volatile phase-change memory, that is, the phase change of the phase-change material from an amorphous state to a crystalline state and vice versa, a pulse voltage is applied to the phase-change material, and a joule heat generation at that time is used. To achieve a phase change of the phase-change material from an amorphous state to a crystalline state, a voltage that provides a temperature equal to or higher than a crystallization temperature and equal to or lower than a melting point is applied. In addition, to achieve a phase change from a crystalline state to an amorphous state, a short-pulse voltage that provides a temperature equal to or higher than the melting point is applied and then it is rapidly cooled. For example, a general PCM structure is disclosed in a document titled “Technology and Materials for Future Optical Memories”, electronics material and technology series, CMC Publishing CO., LTD. issued in 2004, p. 99, FIG. 6 (Non-Patent Document 1). For an electrode film in contact with a phase-change film, high melting point metal such as tungsten or alloy containing tungsten has been examined so as to resist the heat which occurs at the time of switching of the phase-change film.

### SUMMARY OF THE INVENTION

Meanwhile, the non-volatile phase-change memory as described above has a problem that repetitive phase-change switching destroys the phase-change film to disable the rewriting.

Therefore, an object of the present invention is to provide a structure of a non-volatile phase-change memory with its phase-change film resistant to destruction, thereby providing a reliable non-volatile phase-change memory.

The above and other objects and novel characteristics of the present invention will be apparent from the description of this specification and the accompanying drawings.

The typical ones of the inventions disclosed in this application will be briefly described as follows.

According to the present invention, in a non-volatile phase-change memory comprising: an interlayer dielectric film and a plug formed on one main surface side of a semiconductor substrate; a phase-change film which is formed on surfaces of the interlayer dielectric film and the plug and can take a different electric resistivity depending on a phase change; and an electrode film formed on an upper surface of the phase-change film, a straight line Q3 formed by connecting a point P1 on a closed curve Q1 formed by projecting an outer-periphery line of an interface between the phase-change film and the electrode film onto the surface of the interlayer dielectric film and a centroid of a closed curve Q2 formed by an outer periphery of the surface of the plug crosses the closed curve Q2 at a point P2, and a length L of a longest straight line formed by the point P1 on the closed curve Q1 and the point P2 on the closed curve Q2 and a thickness T of the phase-change film have a relation of: 0.3≦L/T≦1.

The effects obtained by typical aspects of the present invention will be briefly described below.

According to the present invention, a relation between a film thickness T of a phase-change film and an amount of projection L of an electrode film from a plug is set to 0.3≦T/T≦1. By this means, the density of current flowing through the phase-change film near the outer periphery of the plug can be reduced, the migration can be suppressed, and further, rewriting can be performed with low energy. Thus, a reliable non-volatile phase-change memory can be achieved.

### BRIEF DESCRIPTIONS OF THE DRAWINGS

FIG. 1 is a cross-sectional view of main parts showing a non-volatile phase-change memory according to an embodiment of the present invention;

FIG. 2 is an enlarged cross-sectional view of the main parts showing the non-volatile phase-change memory according to the embodiment of the present invention;

FIG. 3 is an enlarged plan view of the main parts showing the non-volatile phase-change memory according to the embodiment of the present invention;

FIG. 4 is a drawing showing density of heat generation of the non-volatile phase-change memory according to the embodiment of the present invention;

FIG. 5 is a drawing showing current vectors of the non-volatile phase-change memory according to the embodiment of the present invention;

FIG. 6 is a graph showing a distribution of density of heat generation of the non-volatile phase-change memory according to the embodiment of the present invention;

FIG. 7 is a graph showing a relation between a density of heat generation and L/T of the non-volatile phase-change memory according to the embodiment of the present invention;

FIG. 8 is a graph showing a relation between median time for failure and L/T of the non-volatile phase-change memory according to the embodiment of the present invention;

FIG. 9 is a drawing showing an amorphous-phase distribution (L/T=1) of the non-volatile phase-change memory according to the embodiment of the present invention;

FIG. 10 is a drawing showing an amorphous-phase distribution (L/T=0) of the non-volatile phase-change memory according to the embodiment of the present invention;

FIG. 11 is a drawing showing rewrite characteristics of the non-volatile phase-change memory according to the embodiment of the present invention;

FIG. 12 is a cross-sectional view of main parts showing a manufacturing method of a non-volatile phase-change memory according to the embodiment of the present invention;

FIG. 13 is a cross-sectional view of the main parts in the manufacturing method of a non-volatile phase-change memory according to the embodiment of the present invention (continued from FIG. 12);

FIG. 14 is a cross-sectional view of the main parts in the manufacturing method of a non-volatile phase-change memory according to the embodiment of the present invention (continued from FIG. 13);

FIG. 15 is a cross-sectional view of the main parts in the manufacturing method of a non-volatile phase-change memory according to the embodiment of the present invention (continued from FIG. 14);

FIG. 16 is a cross-sectional view of the main parts in the manufacturing method of a non-volatile phase-change memory according to the embodiment of the present invention (continued from FIG. 15);

FIG. 17 is a cross-sectional view of the main parts in the manufacturing method of a non-volatile phase-change memory according to the embodiment of the present invention (continued from FIG. 16);

FIG. 18 is a drawing for describing operation pulses of the non-volatile phase-change memory according to the embodiment of the present invention; and

FIG. 19 is a drawing for describing temperature transition in an operation of the non-volatile phase-change memory according to the embodiment of the present invention.

### DESCRIPTIONS OF THE PREFERRED EMBODIMENTS

Hereinafter, embodiments of the present invention will be described in detail with reference to the accompanying drawings. Note that components having the same function are denoted by the same reference symbols throughout the drawings for describing the embodiment, and the repetitive description thereof will be omitted.

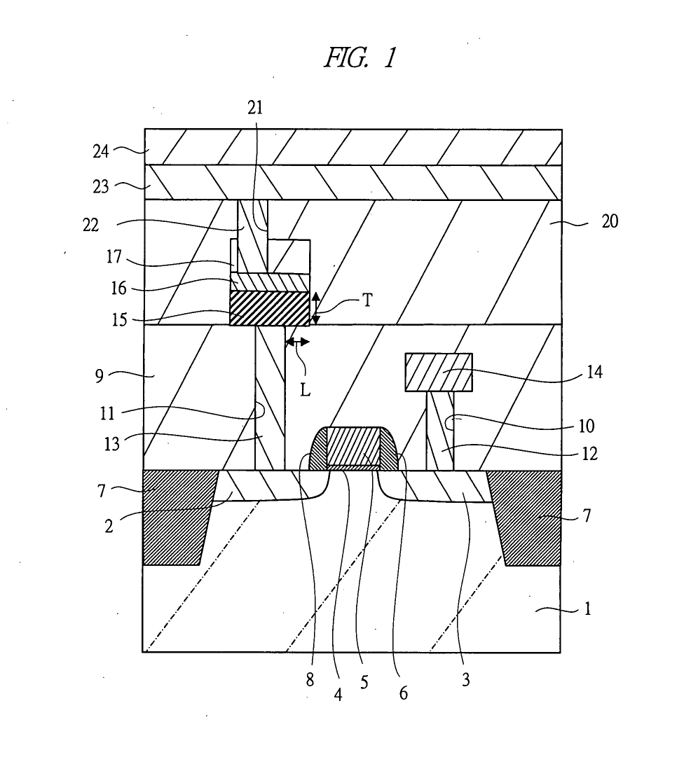

First, a cross-sectional structure of main parts of the non-volatile phase-change memory according to an embodiment of the present invention is shown in FIG. 1 to FIG. 3.

In the non-volatile phase-change memory according to the present embodiment, as shown in FIG. 1, diffusion layers 2 and 3 are formed on a silicon substrate 1, and a gate dielectric film 4 and a gate electrode 5 are formed thereon, thereby forming a metal oxide semiconductor (MOS) transistor 6. The gate dielectric film 4 is, for example, a silicon oxide (SiO₂) film or a silicon nitride (Si₃N₄) film, and the gate electrode 5 is, for example, a polycrystalline silicon film, a metal thin-film, a metal silicide film, or a multilayered structure of these films. The MOS transistor 6 is isolated by an element isolation film 7 formed of, for example, a silicon oxide film. A dielectric film 8 formed of, for example, a silicon oxide film is formed on the gate electrode 5 and a sidewall thereof. A first interlayer dielectric film 9 formed of, for example, a boron-doped phospho-silicate glass (BPSG) film, a spin on glass (SOG) film, or a silicon oxide film or nitride film formed through chemical vapor deposition or sputtering is formed on the entire upper surface of the MOS transistor 6.

Contact holes 10 and 11 are formed in the first interlayer dielectric film 9, and plugs 12 and 13 formed of a main conductive member coated with a barrier film made of, for example, titanium nitride (TiN) for preventing diffusion are formed in the contact holes 10 and 11, and the plugs 12 and 13 are connected to the diffusion layers 2 and 3, respectively. Also, the plug 12 is connected to a wiring 14.

A phase-change film 15 containing, for example, a germanium-antimony-tellurium compound (Ge₂Sb₂Te₅) as a main ingredient, an upper electrode film 16 made of tungsten (W), and a dielectric film 17 formed of a silicon oxide film are formed on the surface of the plug 13 and a part of the surface of the first interlayer dielectric film 9.

A second interlayer dielectric film 20 is formed on the surface of the first interlayer dielectric film 9 and the surface of a multilayered film of the phase-change film 15, the upper electrode film 16, and the dielectric film 17. A contact hole 21 is formed in the second interlayer dielectric film 20, and a plug 22 formed of a conductive member coated with a barrier film made of, for example, titanium nitride for preventing diffusion is formed in the contact hole 21, and the plug 22 is connected to the upper electrode film 16. Further, a wiring layer 23 electrically connected to the plug 22 is formed on the surface of the second interlayer dielectric film 20, and a third interlayer dielectric film 24 is formed on the wiring layer 23. With such a structure, a recording portion of a phase-change memory cell is configured.

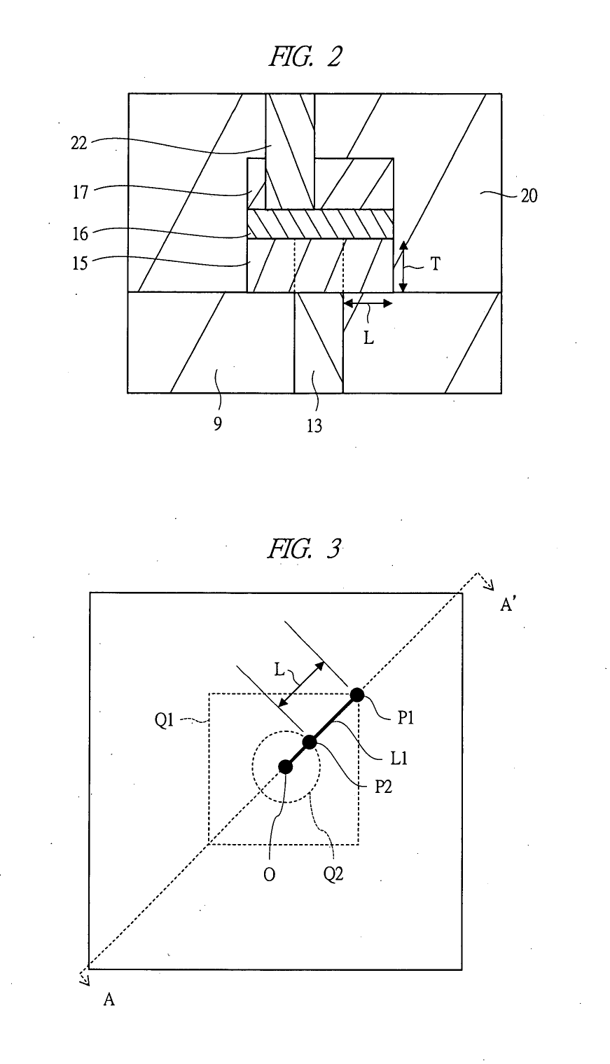

FIG. 2 is an enlarged view showing the periphery of the phase-change film 15 in FIG. 1 and is a cross-sectional view taken along an line A-A′ in a plan view shown in FIG. 3. Here, a closed curve Q1 and a closed curve Q2 in FIG. 3 correspond to a closed curve Q1 formed by projecting an outer peripheral line of an interface between the phase-change film 15 and the upper electrode film 16 onto the interlayer dielectric film 9 and a closed curve Q2 formed by an outer periphery of the surface of the plug 13, respectively. In this case, a straight line L1 formed by connecting a point P1 on the closed curve Q1 and a centroid O of the closed curve Q2 together crosses the closed curve Q2 at a point P2. Also, a length L which is the longest straight line formed by the point P1 on the closed curve Q1 and the point P2 on the closed curve Q2 and a thickness T of the phase-change film 15 have a following relation.
0.3≦L/T≦1 Equation (1)

Here, if the relation between the length L and the thickness T satisfies Equation (1), migration of the phase-change film 15 near the periphery of the plug 13 is suppressed, and write cycle endurance of the non-volatile phase-change memory can be improved. Also, in consideration of ease of a manufacturing process, it is preferable that the closed curve Q1 forms a rectangle and the closed curve Q2 forms a circle as shown in FIG. 3. Needless to say, however, the closed curve Q1 may form another polygon or a circle and the closed curve Q2 may form a rectangle or another polygon. Next, the principle of improvement in write cycle endurance will be described.

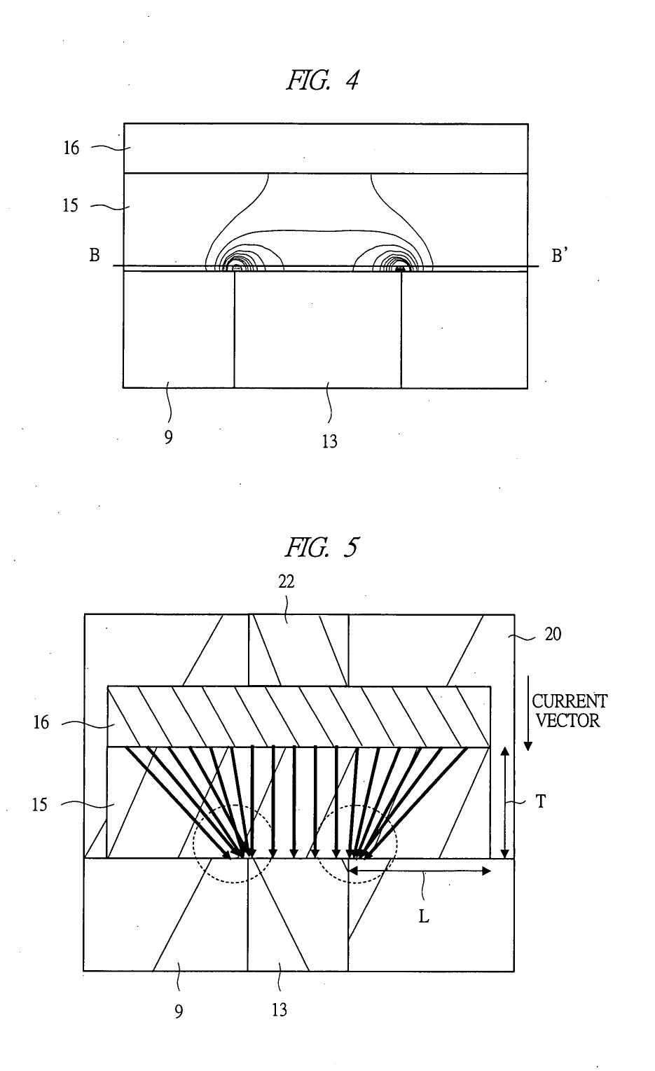

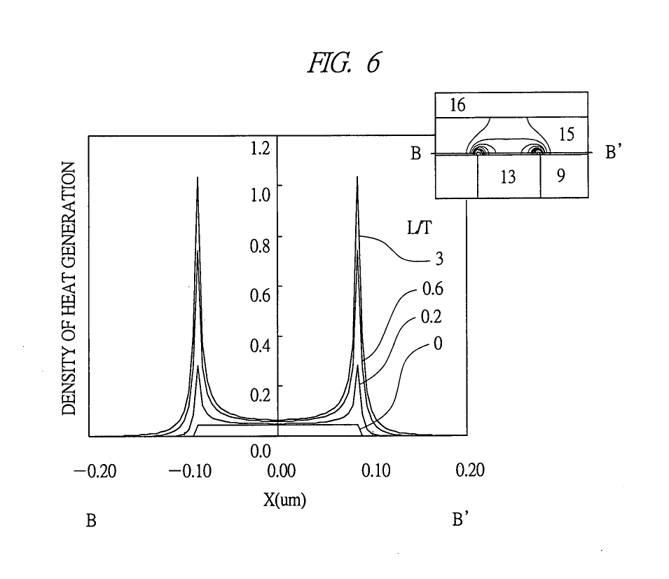

FIG. 4 shows an example of simulation results for a distribution of density of heat generation in the phase-change film in a cross-section taken along the line A-A′ shown in FIG. 3. Also, FIG. 5 is a drawing schematically showing current vectors. In this case, the film thickness T of the phase-change film 15 is 100 nm and the length L is 300 nm. As can be seen from FIG. 4, a portion near the outer periphery of the plug 13 in the phase-change film 15 has a large density of heat generation. The reason why such a large density of heat generation occurs near the outer periphery of the plug 13 is as follows. That is, as shown in FIG. 5, when currents flow from the upper electrode film 16 to the plug 13, the current flow concentrates in the portion near the outer periphery of the plug 13 because the area of the plug 13 is smaller than the area of the upper electrode film 16. Therefore, the current density increases near the outer periphery of the plug 13, and thus the density of heat generation increases. In other words, the current density and the density of heat generation near the outer periphery of the plug 13 (the density of heat generation is proportional to the square of the current density) are associated with the amount of current from outside of the plug 13 and are also associated with the thickness T of the phase-change film 15 and the length L (the amount of protrusion of the upper electrode from the plug).

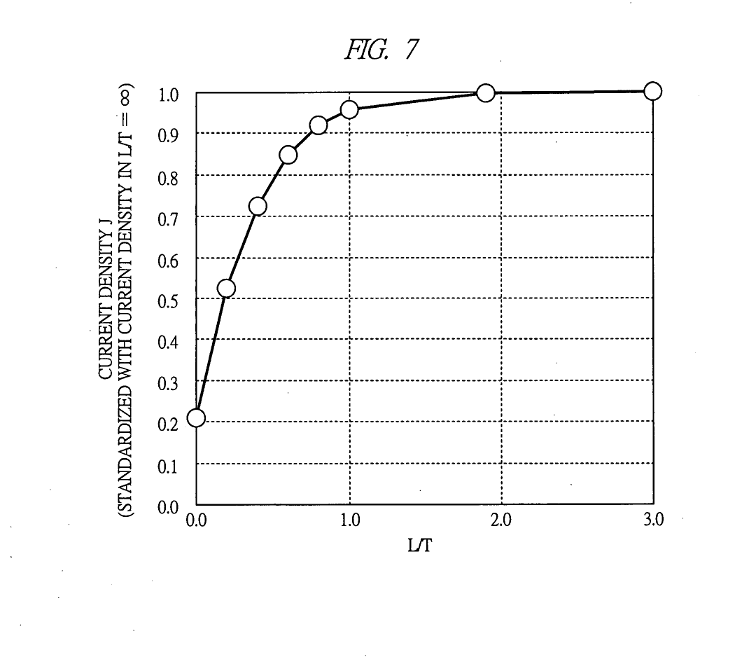

FIG. 6 shows a distribution of density of heat generation on a straight line B-B′ shown in the inserted drawing in the case where a ratio L/T between L and T is 0, 0.2, 0.6, and 3. Also, FIG. 7 is a graph showing a relation between a maximum value of the amount of heat generation (current density J (standardized with a current density in L/T=∞)) and L/T. As can be seen from FIG. 6 and FIG. 7, the density of heat generation decreases as L/T decreases. In particular, a change in density of heat generation is small around L/T=3, but the density of heat generation rapidly decreases in L/T≦1.

The mechanism in which the phase-change film 15 is destroyed and the rewriting is disabled due to the repetition of phase-change switching is considered to be the same as the electromigration that may occur also in wiring. That is, it is due to the atom diffusion by current. As an evaluation equation for median time for failure of electromigration, Black's equation represented by the following Equation (2) is widely used. The Black's equation is described in, for example, a document titled “Next-generation ULSI process technology”, Realize Advanced Technology Limited, issued in 2000, p. 546.
MTF=AJ⁻ⁿexp(Ea/kT) Equation (2)

Here, MTF is an abbreviation of Median Time for Failure, A is a constant, J is a current density, n is an index, and Ea is activation energy. The index n often takes a value of approximately 2.

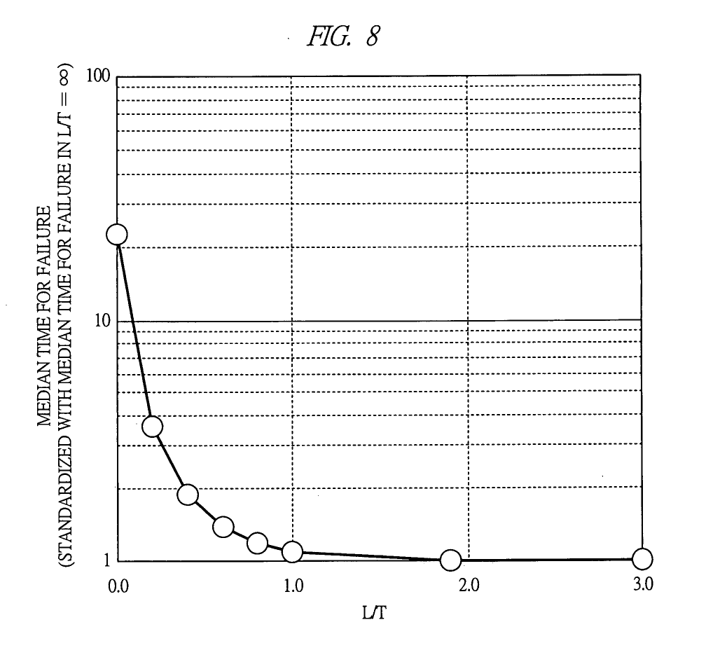

FIG. 8 shows the median time for failure by using the current density in FIG. 7 where n=2 in Equation (2). The vertical axis of FIG. 8 represents the median time for failure of the non-volatile phase-change memory, which is standardized with a median time for failure when L/T is infinite. The median time for failure rapidly increases when L/T≦1. In other words, it can be understood that, in order to decrease the density of heat generation, that is, to decrease the current density to suppress migration, L/T≦1 is preferable.

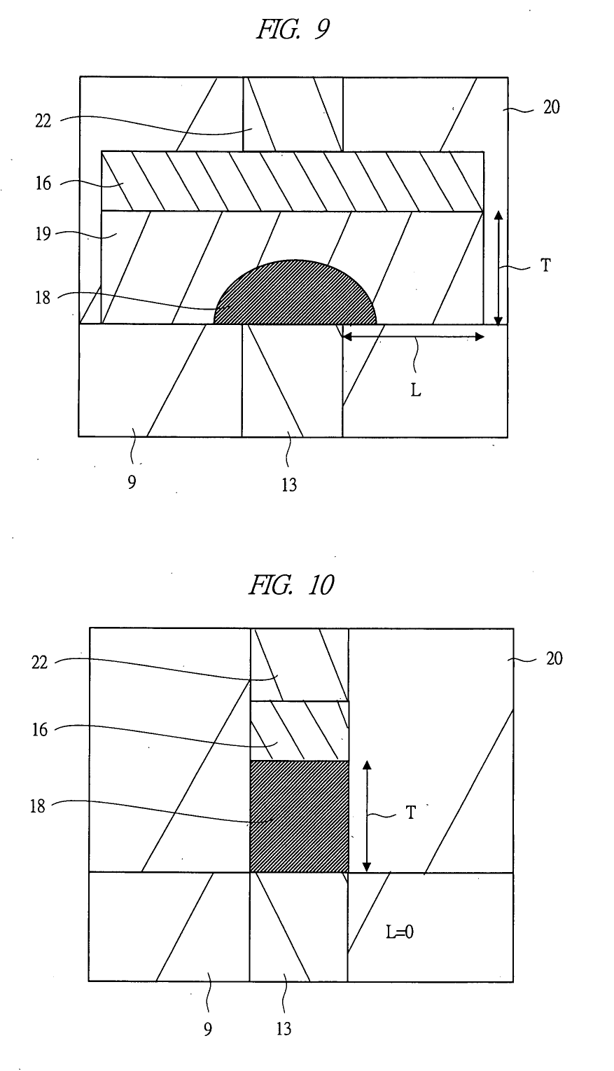

FIG. 9 and FIG. 10 schematically show a distribution of an amorphous phase 18 formed in the phase-change film 15 due to the rewriting (changing the state of a crystalline phase 19 into an amorphous state). FIG. 9 shows an example when L/T=1. FIG. 10 shows an example when L/T=0.

As shown in FIG. 9, when L/T=1, for example, the density of heat generation near the lower plug 13 is larger than the density of heat generation near the upper electrode film 16, and therefore, the amorphous phase 18 occurs in a hemispherical shape so as to cover the surface of the plug 13, and electric resistivity is efficiently increased. On the other hand, when L/T is too small, for example, when L/T=0 as shown in FIG. 10, the current density becomes uniform in the phase-change film 15, and the phase changes occur irrespectively near the plug 13 and near the upper electrode film 16. When the portion around the upper electrode film 16 is changed to be amorphous, it means that larger energy is required for rewriting.

For example, FIG. 11 shows simulation results of changes of electric resistivity of the phase-change film 15 with time at the time of rewriting from crystalline to amorphous (reset rewriting) when the film thickness T of the phase-change film 15 is 100 nm and L/T is 0, 0.2, 0.3, 0.6, 0.8, 1.0, 1.9, and 3.0. A voltage applied to the phase-change film 15 is 1.2 V from 0 nsec to 30 nsec and is 0 V thereafter. Results that changes in resistance are small are obtained in the cases where L/T is 0 and 0.2. In other cases, the resistance is increased 100 times or more. In other words, it represents that rewriting cannot be achieved by the voltage of 1.2 V in the cases where L/T is 0 and 0.2. That is, it can be said that, in order to change only the portion near the plug 13 to be amorphous for achieving the rewriting with a low voltage, L/T≧0.3 is desirable. In other words, by setting 0.3≦L/T≦1, the density of current flowing through the phase-change film 15 near the outer periphery of the plug 13 is decreased, and the migration can be suppressed and the rewriting can be achieved with low energy. Accordingly, a reliable non-volatile phase-change memory can be achieved.

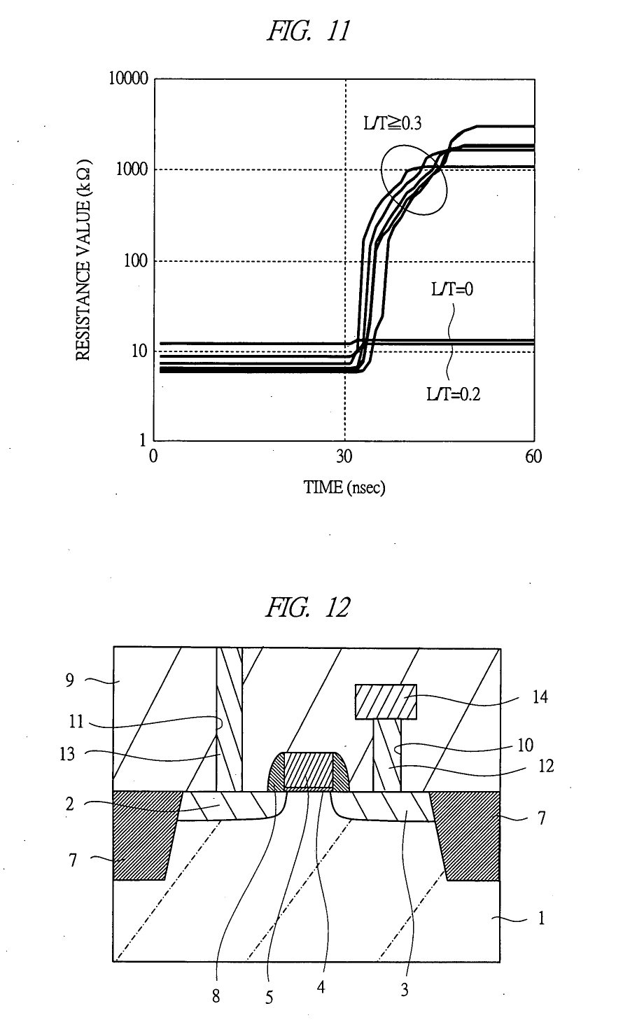

Next, a process of manufacturing the main part of the non-volatile phase-change memory according to the present embodiment will be described with reference to FIG. 12 to FIG. 17.

The non-volatile phase-change memory according to the present embodiment is manufactured as follows. First, as shown in FIG. 12, with a method similar to the conventional method, the diffusion layers 2 and 3 are formed on the silicon substrate 1. On these diffusion layers 2 and 3, the gate dielectric film 4 formed of, for example, a silicon oxide film or silicon nitride film and the gate electrode 5 formed of, for example, a polycrystalline silicon film, a metal thin-film, a metal silicide film, or a multilayered structure thereof are formed to configure the MOS transistor 6. The MOS transistor 6 is isolated by the element isolation film 7 formed of, for example, a silicon oxide film.

Subsequently, the dielectric film 8 formed of, for example, a silicon oxide film is formed on the sidewall of the gate electrode 5. Thereafter, a first interlayer dielectric film 9 formed of, for example, a BPSG film, an SOG film, or a silicon oxide film or nitride film formed through chemical vapor deposition or sputtering is formed on the entire upper surface of the MOS transistor 6. Then, after the contact holes 10 and 11 are formed in the first interlayer dielectric film 9, the plugs 12 and 13 formed of a main conductive member coated with a barrier film made of, for example, titanium nitride for preventing diffusion are formed in the contact holes 10 and 11. Lower portions of the plugs 12 and 13 are connected to the diffusion layers 2 and 3, respectively. An upper portion of the plug 12 is connected to the wiring 14.

At this time, the surfaces of the first interlayer dielectric film 9 and the plug 13 are planarized through chemical mechanical polishing (CMP) or the like. By doing so, a planarized structure is achieved as shown in FIG. 12.

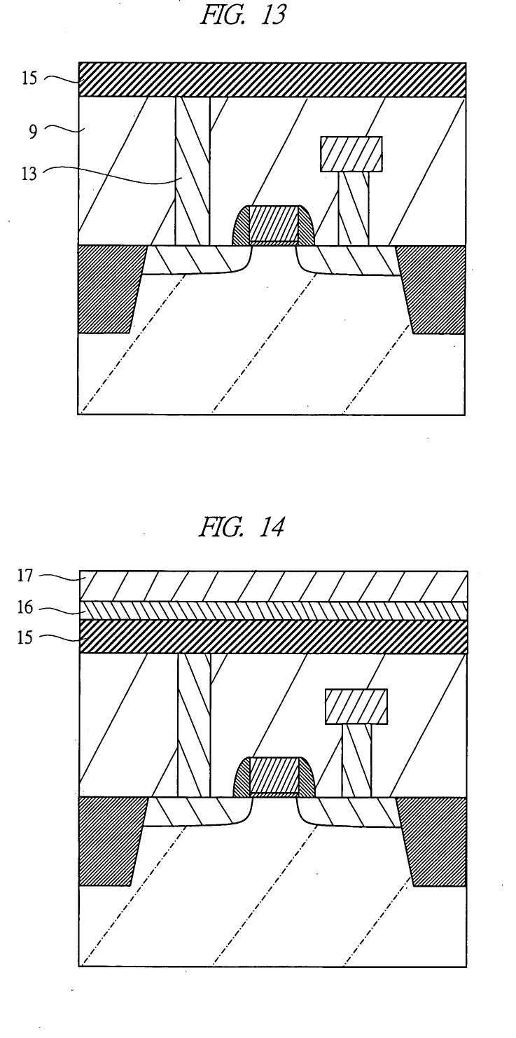

Next, as shown in FIG. 13, the phase-change film 15 formed of, for example, a germanium-antimony-tellurium compound is formed on the surface of the first interlayer dielectric film 9 and the plug 13 through, for example, sputtering.

Next, as shown in FIG. 14, the upper electrode film 16 made of tungsten is formed through sputtering, and the dielectric film 17 formed of a silicon oxide film is formed through CVD.

Subsequently, as shown in FIG. 15, the dielectric film 17, the upper electrode film 16, and the phase-change film 15 are patterned through dry etching to form a memory writing-portion. At this time, the relation between the film thickness T of the phase-change film 15 and the length L (the amount of protrusion of the upper electrode film from the plug) is set to 0.3≦L/T≦1.

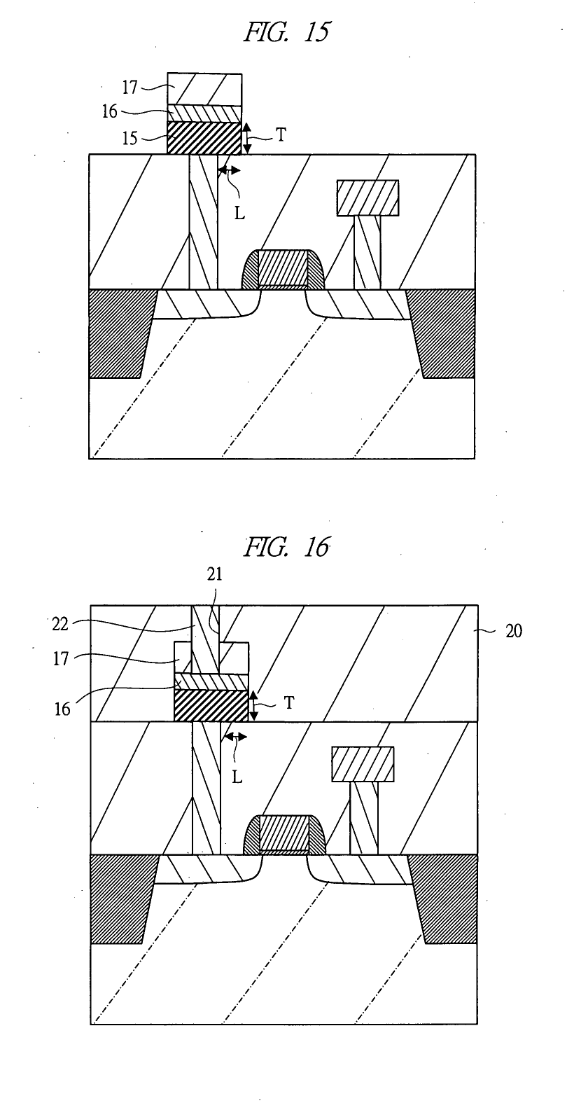

Subsequently, as shown in FIG. 16, the second interlayer dielectric film 20 is formed through CVD, and a part of the second interlayer dielectric film 20 and a part of the dielectric film 17 are etched to form the contact hole 21, in which the plug 22 made of, for example, tungsten is formed through sputtering. The plug 22 is electrically connected to the upper electrode film 16. The surfaces of the second interlayer dielectric film 20 and the plug 22 are planarized through CMP or the like. By doing so, a planarized structure is achieved as shown in FIG. 16.

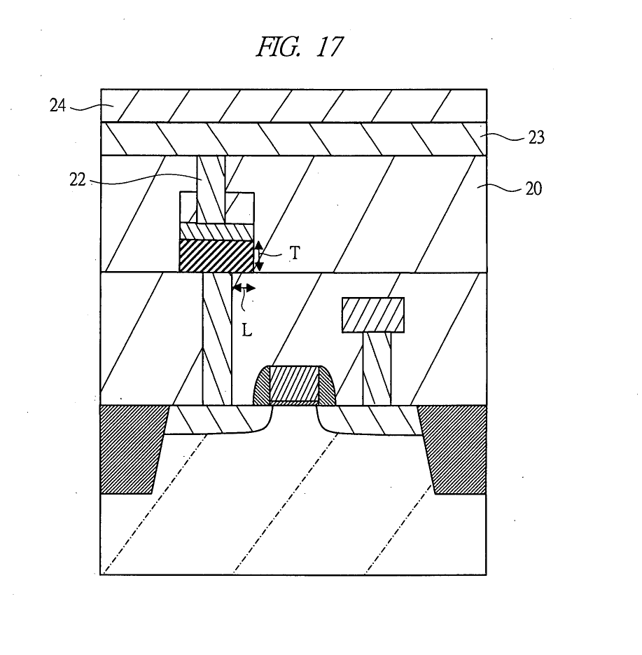

Subsequently, as shown in FIG. 17, the wiring layer 23 made of aluminum is formed through, for example, sputtering on the surfaces of the second interlayer dielectric film 20 and the plug 22, and the third interlayer dielectric film 24 is formed further thereon through CVD. In this manner, main parts of a memory cell of the non-volatile phase-change memory as shown in FIG. 17 can be formed.

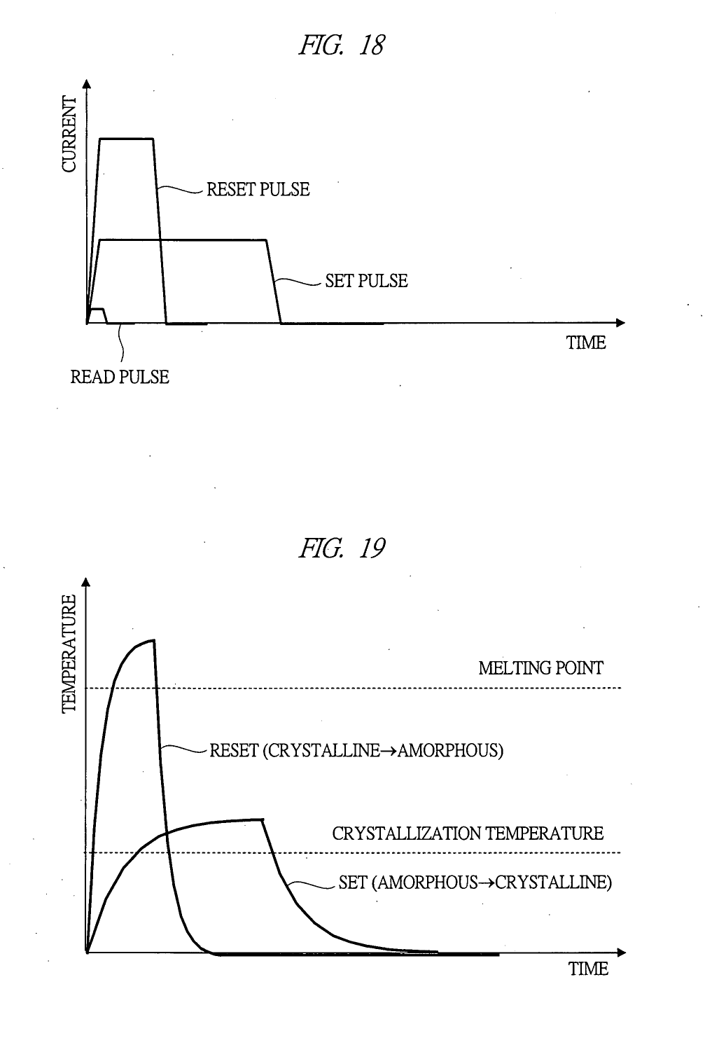

Next, the operation principle of the non-volatile phase-change memory according to the present embodiment will be described with reference to FIG. 18 and FIG. 19.

The non-volatile phase-change memory is a device obtained by applying a phase-change material for use in a DVD recording medium to a semiconductor memory. In the DVD recording medium, the phase-change material is changed to an amorphous or crystalline state with a laser pulse, and by means of the difference in refraction index between the amorphous state and the crystalline state, information is recorded. On the other hand, in the PCM, a pulse voltage is applied to the memory cell, and the voltage and a pulse time are adjusted to select either one of the amorphous state and the crystalline state. At this time, since the electric resistivity varies 100 times or more between the amorphous state and the crystalline state, information is recorded by means of the difference in electric resistivity.

As shown in FIG. 18, in the switching (reset) of the memory cell from a crystalline state to an amorphous state, a short-time pulse (reset pulse) with a relatively large current is fed, and in the switching (set) from an amorphous state to a crystalline state, a long-time pulse (set pulse) with a relatively small current is fed. Also, at the time of reading, a short-time pulse with a small current (read pulse) is fed to the memory cell to read information of the memory based on a resistance value of the memory cell.

As shown in FIG. 19, since a large current flows by the reset pulse, the memory cell is melted, and the cooling thereof is rapidly performed due to its short pulse width. Therefore, the state of the memory cell is changed to an amorphous state. On the other hand, by the set pulse, a current with which the temperature of the memory cell exceeds the crystallization temperature is fed. Therefore, the memory cell is changed from an amorphous state to a crystalline state.

For example, it is confirmed that an element in which a phase-change film is made of Ge₂Sb₂Te₅ and has a thickness of 100 nm, a plug in contact with the phase-change film has a diameter of 180 nm, the amount of protrusion L of the upper electrode film from the plug is 80 nm (T/L≧0.8), and resistance in a set state (memory cell is in a crystalline state) is about 6 kohm is reset (the memory cell is changed to an amorphous state) by a high-voltage short pulse with a voltage of 1.2 V and a pulse width of 60 nsec, and its resistance is approximately 3 megohm, that is, the resistance is increased about 500 times. Also, it is confirmed that the element in a reset state (the memory cell is in an amorphous state) is changed to a memory-set state (the memory cell is crystallized) by a low-voltage long pulse with a voltage of 1.8 V and a pulse width of 1.2 msec, and its resistance is approximately 6 kohm. It is also confirmed that, in memory rewriting, the resistance values in a reset state and a set state are stably repeated, and 106 rewrite cycles or more with an approximately 500-fold ratio therebetween can be achieved. Thus, it is confirmed that the element can operate as a memory.

In the foregoing, the invention made by the inventors of the present invention has been concretely described based on the embodiments. However, it is needless to say that the present invention is not limited to the foregoing embodiments and various modifications and alterations can be made within the scope of the present invention.

The present invention relates to a technology for a non-volatile phase-change memory. In particular, it can be used for a structure of the non-volatile phase-change memory and a manufacturing method thereof.

What is claimed is:

1. A non-volatile phase-change memory comprising:
an interlayer dielectric film and a plug formed on one main surface side of a semiconductor substrate;
a phase-change film which is formed on surfaces of the interlayer dielectric film and the plug and can take a different electric resistivity depending on a phase change; and
an electrode film formed on an upper surface of the phase-change film,
wherein a straight line Q3 formed by connecting a point P1 on a closed curve Q1 formed by projecting an outer-periphery line of an interface between the phase-change film and the electrode film onto the surface of the interlayer dielectric film and a centroid of a closed curve Q2 formed by an outer periphery of the surface of the plug crosses the closed curve Q2 at a point P2, and
a length L of a longest straight line formed by the point P1 on the closed curve Q1 and the point P2 on the closed curve Q2 and a thickness T of the phase-change film have a relation of: 0.3≦L/T≦1.

2. The non-volatile phase-change memory according to claim 1,
wherein the closed curve Q1 forms a rectangle, and the closed curve Q2 forms a circle.

3. A manufacturing method of a non-volatile phase-change memory, comprising the steps of:
forming an interlayer dielectric film and a plug on one main surface side of a semiconductor substrate;
forming a phase-change film, which can take a different electric resistivity depending on a phase change, on surfaces of the interlayer dielectric film and the plug; and
forming an electrode film on an upper surface of the phase-change film,
wherein, in the step of forming the phase-change film, the phase-change film is formed so that:
a straight line Q3 formed by connecting a point P1 on a closed curve Q1 formed by projecting an outer-periphery line of an interface between the phase-change film and the electrode film onto the surface of the interlayer dielectric film and a centroid of a closed curve Q2 formed by an outer periphery of the surface of the plug crosses the closed curve Q2 at a point P2, and
a length L of a longest straight line formed by the point P1 on the closed curve Q1 and the point P2 on the closed curve Q2 and a thickness T of the phase-change film have a relation of: 0.3≦L/T≦1.

4. The manufacturing method of a non-volatile phase-change memory according to claim 3,
wherein the closed curve Q1 forms a rectangle, and the closed curve Q2 forms a circle.

5. A non-volatile phase-change memory in which an interlayer dielectric film and a plug are formed on one main surface side of a semiconductor substrate, a phase-change film which can take a different electric resistivity depending on a phase change is formed on surfaces of the interlayer dielectric film and the plug, and an electrode film is formed on an upper surface of the phase-change film,
wherein a relation between a film thickness T of the phase-change film and an amount of protrusion L of the electrode film from the plug is represented by: 0.3≦L/T≦1.
